(19) United States
(12) Patent Application Publication
(10) Pub. No.: US 2024/0371679 A1
(43) Pub. Date: Nov. 7, 2024

(54) CLOCKABLE SUBSTRATE PROCESSING PEDESTAL FOR USE IN SEMICONDUCTOR FABRICATION TOOLS

(71) Applicant: LAM RESEARCH CORPORATION, Fremont, CA (US)

(72) Inventors: Sky MULLENAUX, Tigard, OR (US); Chirag Raghunath SHIVDAS, Ahmedabad, GJ (IN); Nick Ray LINEBARGER, JR., Beaverton, OR (US)

(21) Appl. No.: 18/682,216

(22) PCT Filed: Oct. 19, 2021
(86) PCT No.: PCT/US2021/055541

§ 371 Date: Feb. 8, 2024

(30) Foreign Application Priority Data
Aug. 14, 2021 (IN) 202111036892

(51) Int. Cl. H01L 21/687; H01J 37/32; H01L 21/67; H01L 21/68

(52) U.S. Cl. CPC H01L 21/68785; H01J 37/32715; H01L 21/6719; H01L 21/68; H01J 2237/3321

(57) ABSTRACT

A dockable pedestal configured to support a substrate in a processing station comprises a baseplate, a stem, and a plurality of dowels arranged around the stem. The plurality of dowels is configured to be inserted within designated receiving slots in a first surface of the processing station to reduce misalignment and promote proper tuning range of the dockable pedestal. At least one of the plurality of dowels has a diameter that is larger than the diameters of other dowels. The dowel with the larger diameter is configured to fit within only one of the designated receiving slots in the first surface of the processing station.

### CROSS-REFERENCE TO RELATED APPLICATIONS

This application claims the benefit of Indian Patent Application No. 202111036892, filed on Aug. 14, 2021. The entire disclosure of the application referenced above is incorporated herein by reference.

### FIELD

The present disclosure relates to a clockable pedestal with advanced alignment features configured to operate in substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems are used to perform treatments such as deposition and etching of film on substrates such as semiconductor wafers. For example, deposition may be performed to deposit conductive film, dielectric film, or other types of film using chemical vapor deposition (CVD), plasma enhanced CVD (PECVD), atomic layer deposition (ALD), plasma enhance ALD (PEALD), and/or other deposition processes. During deposition, the substrate is arranged on a substrate support (e.g., a pedestal) and one or more precursor gases may be supplied to a processing chamber using a gas distribution device (e.g., a showerhead) during one or more process steps. In a PECVD or PEALD process, plasma is used to activate chemical reactions within the processing chamber during deposition.

Correct installation of conventional pedestals can be both time consuming and error prone. Pedestals in substrate processing systems are configured to interact or interface with various moving components in close proximity such as substrate transfer robots. If a pedestal is not properly aligned during installation, the pedestal may come in contact with the moving components in operation and cause it to vibrate or generate contaminant particles. Sometimes proper alignment takes a long time to achieve because the operator would need to adjust and re-clamp the pedestal multiple times to make sure that no moving components are too close to the pedestal. Therefore, there is a need for pedestal assemblies that can avoid misalignment and provide confined positional tuning to allow operators to find the correct station-specific alignment quickly.

### SUMMARY

A clockable pedestal configured to support a substrate in a processing station of a substrate processing system comprises a baseplate, a stem that extends downward from the baseplate, and a plurality of dowels arranged around the stem that extend downward from the clockable pedestal according to some embodiments of the present disclosure. In some embodiments, the plurality of dowels comprises at least two dowels. In some embodiments, the plurality of dowels comprises at least three dowels, such as a first dowel, a second dowel, and a third dowel. In some embodiments, the plurality of dowels are evenly circumferentially spaced around the stem. Each of the dowels is configured to be inserted within a respective one of a plurality of slots in a first surface of the processing station.

In some embodiments, the plurality of slots comprises a first slot, a second slot, and a third slot, and a width of the first slot is greater than widths of each of the second slot and the third slot. In some embodiments, a diameter of the first dowel is greater than diameters of each of the second dowel and the third dowel. In some embodiments, the diameter of the first dowel is less than the width of the first slot and greater than the widths of the second slot and the third slot. In some embodiments, the diameter of the first dowel is 70-80% of the width of the first slot.

In some embodiments, the clockable pedestal comprises a bottom plate arranged around the stem below the baseplate and the dowels extend downward from the bottom plate. The plurality of dowels comprises three dowels. The diameters of the second dowel and the third dowel are the same and the widths of the second slot and the third slot are the same. In some embodiments, the diameter of the first dowel is at least approximately 24% less than the width of the first slot and at least approximately 5% greater than the widths of the second slot and the third slot.

In some embodiments, the diameters of the second slot and the third slot are approximately 34-35% than the widths of the second slot and the third slot, respectively. In some embodiments, a range of movement of the first dowel within the first slot is at least +/−0.76 mm in an x direction. In some embodiments, a range of movement of the clockable pedestal when installed within the processing station is at least +/−0.76 mm in each of an x direction and a y direction that is perpendicular to the x direction. In some embodiments, a process module comprises a plurality of processing stations comprises at least four of the clockable pedestals arranged in respective ones of the plurality of processing stations.

In some embodiments, a clockable pedestal assembly configured to support a substrate in a process module of a substrate processing system comprises a clockable pedestal. A baseplate of the clockable pedestal comprising a plurality of alignment features defined in a radially outer edge of the baseplate. A plurality of dowels is aligned with and configured to be received by a plurality of slots in a first surface of the process module. The plurality of dowels and the plurality of slots are sized to allow clocking of the clockable pedestal and the plurality of alignment features. In some embodiments, the clockable pedestal assembly comprises a first O-ring and a second O-ring disposed between a bottom plate of the clockable pedestal and the first surface of the process module and the plurality of dowels is located between the first O-ring and the second O-ring. In some embodiments, the clockable pedestal assembly comprises a clamp assembly configured to clamp the clockable pedestal to a pedestal base of the process module.

In some embodiments, a process module for a substrate processing system comprises four processing stations. Each of the processing stations comprises a clockable pedestal assembly, a pedestal base, an opening for receiving a stem of the clockable pedestal assembly, and three slots arranged around the opening. In some embodiments, a width of one of the slots is greater than widths of the other slots. In some embodiments, four clockable pedestals are arranged in the four processing stations. When arranged, each of the four clockable pedestals has a stem that extends downward into the opening. Three dowels extend downward from the clockable pedestal and into the three slots arranged around the opening.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example substrate processing system according to the present disclosure;

FIGS. 2A and 2B show a plan view of an example process module according to the present disclosure;

FIG. 2C is an isometric view of an example pedestal according to the present disclosure;

FIGS. 3A and 3B show example dowels and slots for clocking an example pedestal according to the present disclosure;

FIG. 3C illustrates an example range of movement of a pedestal according to the present disclosure;

FIG. 4A shows another plan view of an example process module and a transfer plate according to the present disclosure; and

FIG. 4B shows a side cross-sectional view of an example pedestal assembly according to the present disclosure.

In the drawings, reference numbers may be reused to identify similar and/or identical elements.

### DETAILED DESCRIPTION

A processing chamber (or a processing module) for a substrate processing system comprises one or more processing stations. For example, a processing chamber may be configured as a quad station module (QSM) that comprises four processing stations. Each processing station may have a clockable pedestal installed within. Each clockable pedestal may comprise a stem that supports a baseplate and a substrate support surface (e.g., a ceramic/metal layer or other planar surface configured to support a substrate during processing).

Each clockable pedestal may comprise one or more clocking (e.g., alignment) features to facilitate alignment and confine movement of the clockable pedestal relative to the processing station. Accurate clocking ensures that a center of each pedestal is a same radial distance from a center of a multi-station process module. For example, a spindle and robot arm assembly may be configured to rotate about an axis aligned with a center of the process module to transfer substrates to and from respective pedestals. Accordingly, the clockable pedestals may be clocked to align with rotational positions of the spindle to facilitate accurate placement of substrates on the clockable pedestals. For example, in a QSM, each clockable pedestal is 90 degrees of rotation from adjacent pedestals.

For example, the processing station may comprise a pedestal base or socket/opening configured to receive the stem of a clockable pedestal. The clocking features (e.g., dowels or pins extending downward from a surface (e.g., a lower surface) of the clockable pedestal) are configured to interface with complementary features in the pedestal base (e.g., slots configured to receive the dowels).

The dowels and slots are sized to ensure that the clockable pedestal is correctly aligned with the processing station and the dowels are not inadvertently inserted into the incorrect slot. In other words, the dowels of the clockable pedestal are configured to ensure that the clockable pedestal can only be installed in one rotational position. For example, the dowels may have different diameters such that one or more of the dowels can only be inserted into a specific one of the slots. In some embodiments, the dowels and slots are further sized in accordance with manufacturing tolerances that are selected to ensure correct alignment and clocking. For example, manufacturing tolerances are limited to prevent any of the dowels from being inserted into the incorrect slot. However, limiting the manufacturing tolerances limits the range that a pedestal can be tuned (or clocked). If the pedestal is not tuned to an optimal position (e.g., the optimal position is outside of the range set by manufacturing tolerances), the pedestal may cause undesirable vibration and particle generation caused by contact between the pedestal and other structures of the process module.

Clockable pedestals and pedestal clocking methods according to the present disclosure are configured to allow a greater range of adjustment of the pedestal position while preventing misalignment and incorrect clocking. For example, one or more of the dowels according to the present disclosure is sized to maximize clocking range of movement while preventing insertion of the dowels into the incorrect slot. As used herein, “clocking” refers to controlled/confined tuning of a position of the clockable pedestal (e.g., in x, y, and rotational directions) relative to the pedestal base. In some embodiments, the clockable pedestal is comprised of a metal or metal alloy such as aluminum, aluminum alloys (e.g., aluminum alloy 3003, 6061, or 5052), etc. In some embodiments, the clockable pedestal is made of other materials such as ceramic.

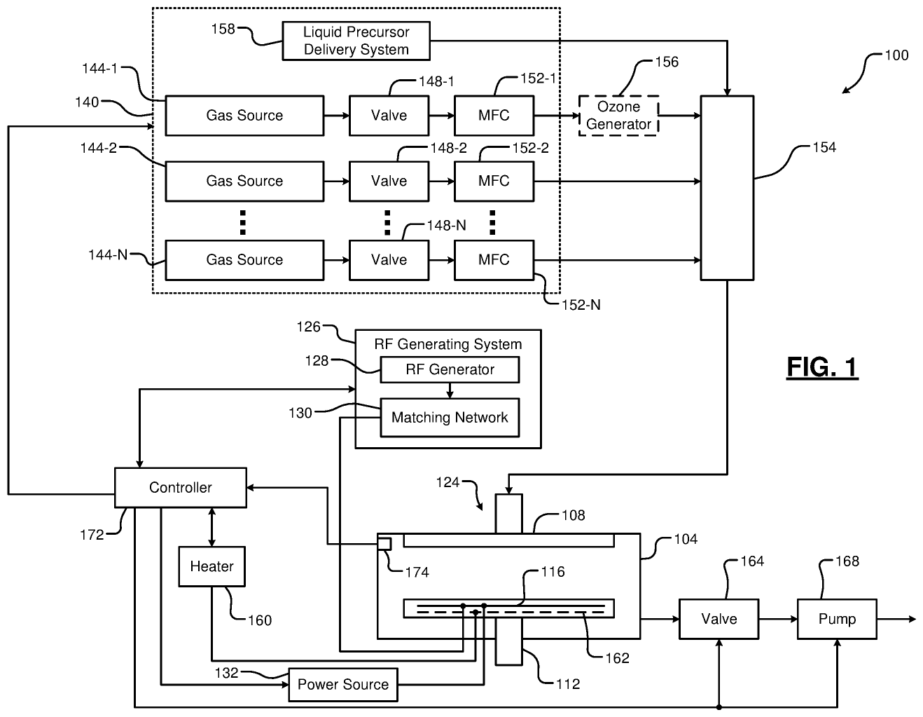

Referring to FIG. 1, an example of a substrate processing system 100 according to the principles of the present disclosure is shown. While the foregoing example relates to PECVD systems, other plasma-based substrate processing chambers may be used. The substrate processing system 100 comprises a processing chamber 104 that encloses other components of the substrate processing system 100. The substrate processing system 100 comprises a first electrode (e.g., an upper electrode) 108 and a substrate support such as a pedestal 112 comprising a second electrode (e.g., a lower electrode) 116. A substrate (not shown) is arranged on the clockable pedestal 112 between the first electrode 108 and the second electrode 116 during processing. The clockable pedestal 112 according to the present disclosure comprises features configured to align the clockable pedestal 112 within the processing chamber 104 as described below in more detail. While described below with respect to a single processing chamber 104 and pedestal 112, the principles of the present disclosure may be implemented in systems comprising multiple processing chambers and processing chambers comprising multiple processing stations and pedestals, such as a quad station module (QSM).

For example, the first electrode 108 may comprise a showerhead 124 that introduces and distributes process gases. In some examples, the showerhead 124 may not be configured for active temperature control. For example, the showerhead 124 is not configured to be actively heated and/or cooled (e.g., using resistive heaters, coolant flowed through coolant channels, etc.). In other words, the showerhead 124 does not comprise active heating components (e.g., embedded resistive heaters) and/or does not comprise active cooling components (e.g., channels configure to flow coolant throughout the showerhead 124). The second electrode 116 may correspond to a conductive electrode embedded within a non-conductive pedestal. Alternately, the clockable pedestal 112 may comprise an electrostatic chuck that comprises a conductive plate that acts as the second electrode 116.

A radio frequency (RF) generating system 126 generates and outputs an RF voltage to the first electrode 108 and/or the second electrode 116 when plasma is used. In some examples, one of the first electrode 108 and the second electrode 116 may be DC grounded, AC grounded, or at a floating potential. For example, the RF generating system 126 may comprise one or more RF voltage generators 128 (e.g., a capacitively-coupled plasma RF power generator, a bias RF power generator, and/or other RF power generator) such as an RF generator 128 that generate RF voltages. The RF voltages are fed by one or more matching and distribution networks 130 to the second electrode 116 and/or the first electrode 108. For example, as shown, the RF generator 128 provides an RF and/or bias voltage to the second electrode 116. The second electrode 116 may receive power alternatively or additionally from other power sources, such as a power source 132. In other examples, an RF voltage may be supplied to the first electrode 108 or the first electrode 108 may be connected to a ground reference.

An example gas delivery system 140 comprises one or more gas sources 144-1, 144-2, . . . , and 144-N (collectively gas sources 144), where N is an integer greater than zero. The gas sources 144 supply one or more gases (e.g., precursors, inert gases, etc.) and mixtures thereof. Vaporized precursor may also be used. At least one of the gas sources 144 may contain gases used in the pre-treatment process of the present disclosure (e.g., NH₃, N₂, etc.). The gas sources 144 are connected by valves 148-1, 148-2, . . . , and 148-N (collectively valves 148) and mass flow controllers 152-1, 152-2, . . . , and 152-N (collectively mass flow controllers 152) to a manifold 154. An output of the manifold 154 is fed to the processing chamber 104. For example, the output of the manifold 154 is fed to the showerhead 124.

In some examples, an optional ozone generator 156 may be provided between the mass flow controllers 152 and the manifold 154. In some examples, the substrate processing system 100 may comprise a liquid precursor delivery system 158. The liquid precursor delivery system 158 may be incorporated within the gas delivery system 140 as shown or may be external to the gas delivery system 140. The liquid precursor delivery system 158 is configured to provide precursors that are liquid and/or solid at room temperature via a bubbler, direct liquid injection, vapor draw, etc.

A heater 160 may be connected to a heater coil 162 arranged in the clockable pedestal 112 to heat the clockable pedestal 112. The heater 160 may be used to control a temperature of the clockable pedestal 112 and the substrate.

A valve 164 and pump 168 may be used to evacuate reactants from the processing chamber 104. A controller 172 may be used to control various components of the substrate processing system 100. For example, the controller 172 may be used to control flow of process, carrier, and precursor gases, striking and extinguishing plasma, removal of reactants, monitoring of chamber parameters, etc. The controller 172 may receive measurement signals indicative of process parameters, conditions within the processing chamber 104, etc. via one or more sensors 174 arranged throughout the substrate processing system 100.

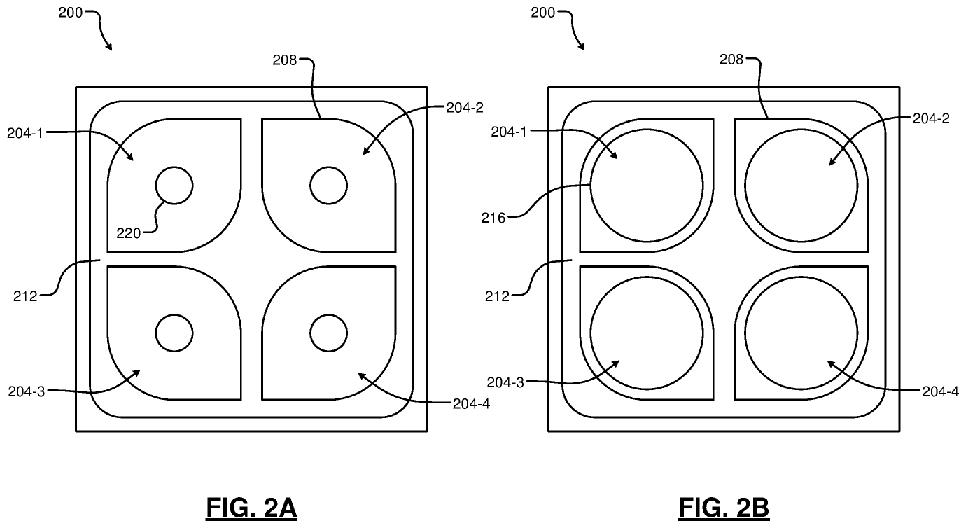

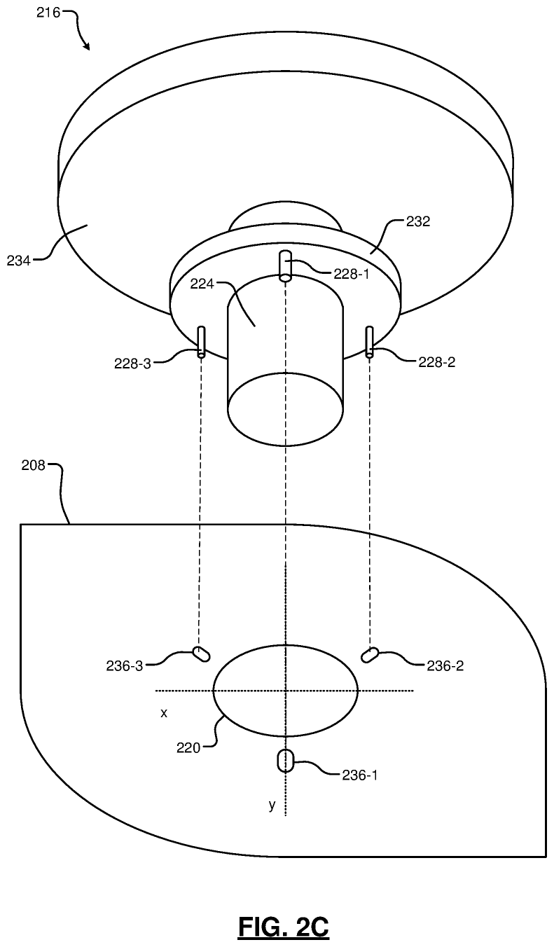

Referring to FIGS. 2A, 2B, and 2C, an example process module (e.g., a QSM) 200 comprises four processing stations 204-1, 204-2, 204-3, and 204-4 (referred to collectively as processing stations 204). As shown in FIG. 2A, each of the processing stations 204 comprises a respective pedestal base 208. In some embodiments, the pedestal base 208 is within a recess or socket defined within a first support surface (e.g., an upper support surface) 212 of the process module 200. The pedestal base 208 is configured to receive and support a respective clockable pedestal 216 as shown in FIG. 2B. For example, the pedestal base 208 comprises an opening 220 arranged to receive a stem 224 extending downward from the clockable pedestal 216 as shown in FIG. 2C.

Referring to FIG. 2C, in some embodiments, the clockable pedestal 216 comprises a plurality of (e.g., three) clocking features (e.g., dowels, pins, or posts) 228-1, 228-2, and 228-3, referred to collectively as dowels 228. For example, the dowels 228 extend downward from a bottom plate or disc 232 arranged around the stem 224 of the clockable pedestal 216. In other examples, the dowels 228 extend downward from a surface (e.g., a bottom surface) of a baseplate 234. For example, each of the dowels 228 has a length of approximately 0.50 inches (e.g., between 0.475 and 0.525 inches, or 12.065 and 13.335 mm). In some embodiments, the dowels 228 may be evenly spaced (e.g., at approximately 120 degree intervals) circumferentially around the stem 224. In some embodiments, dowels 228 are not evenly spaced. In some embodiments, all dowels 228 are equidistant from the stem. In some embodiments, one or more of the dowels 228 may be spaced a different distance from the stem 224 relative to others of the dowels 228.

The dowels 228 are aligned with complementary clocking features on the pedestal base 208, such as slots 236-1, 236-2, and 236-3 (referred to collectively as slots 236) configured to receive respective ones of the dowels 228. The dowels 228 and the slots 236 are sized to ensure that the clockable pedestal 216 is correctly aligned with the pedestal base 208 and, correspondingly, the processing station 204. In other words, the dowels 228 ensure that the clockable pedestal 216 can only be installed in one rotational position or orientation relative to the pedestal base 208. For example, the dowel 228-1 may have a different diameter/shape/size/engaging mechanism relative to the dowels 228-2 and 228-3 such that the dowel 228-1 can only be inserted into the slot 236-1.

In some embodiments, the dowel 228-1 is larger than the dowels 228-2 and 228-3 and is too large to fit into either of the slots 236-2 and 236-3. Accordingly, manufacturing tolerances may be limited to prevent the dowel 228-1 from being small enough to be inserted into the slots 236-2 and 236-3. “Manufacturing tolerances” refers to an amount that a particular dimension of a particular component is permitted to vary. In other words, if manufacturing tolerances are too large, the dowel 228-1 could inadvertently be small enough to fit into one of the slots 236-2 and 236-3. However, limiting the manufacturing tolerances may also limit the range of horizontal and rotational movement of the clockable pedestal 216 relative to the pedestal base 208. For example, if the lower bound of the manufacturing tolerance of the dowels 228-1 is too large (e.g., well beyond the width of slots 236-2 and 236-3), dowel 228-1 would have a smaller range of movement within slot 236-1 compared to if the lower bound manufacturing tolerance is set to be just slightly bigger than the width of slots 236-2 and 236-3. In other words, the larger the diameter of the dowel 228-1 relative to the slot 236-1, the lower the range of movement of the dowel 228-1 and, therefore, the clockable pedestal 216. If the range of horizontal/rotational movement is too restrictive, the clockable pedestal 216 may not be able to reach the optimal station-specific position or may encounter thermal expansion issues. In contrast, if the range of the horizontal/rotational movement is too large, it may take longer to find that optimal station-specific position. Hence, relative sizes and manufacturing tolerances of the dowels are important to achieve optimal pedestal clocking. Further, the range of manufacturing tolerances may be selected to account for thermal expansion of the dowels 228 during high temperature processing. For this reason, in some embodiments, each of the dowels 228 is not be sized to be within 95%, 96%, 97%, 98% or 99% of the respective slot 236's width. In some embodiments, each dowel 228 is not sized to be within 90-100% of the width of the respective slot 236.

The dowels 228 and the slots 236 in some embodiments of the present disclosure are sized to allow a greater range of movement of the clockable pedestal 216 while preventing misalignment. For example, the dowel 228-1 is sized to maximize clocking range of movement (e.g., movement in x, y, and rotational directions) while preventing misalignment (i.e., insertion of the dowel 228-1 into either of the slots 236-2 and 236-3) as described below in more detail.

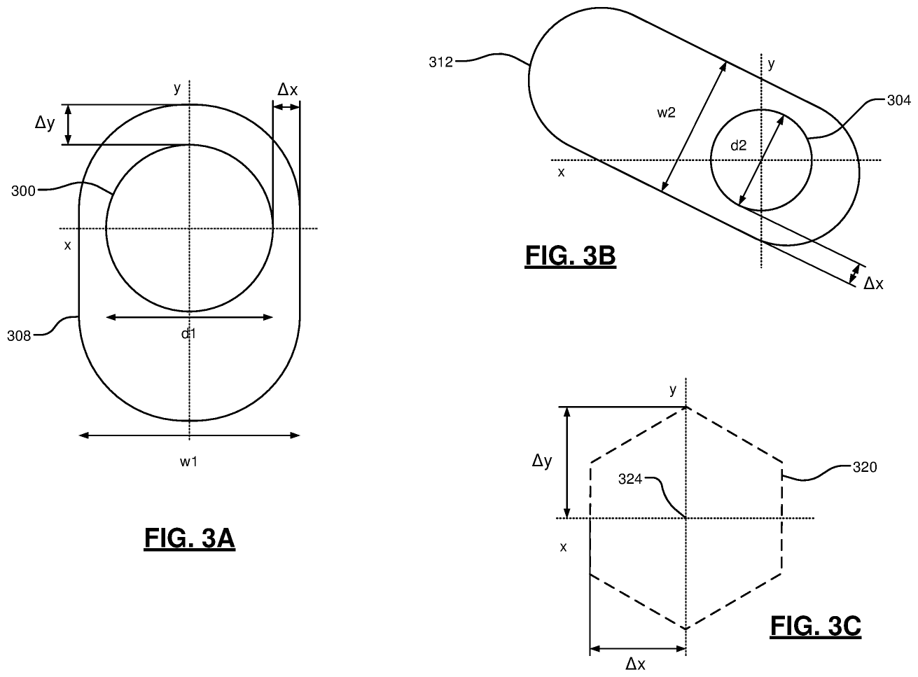

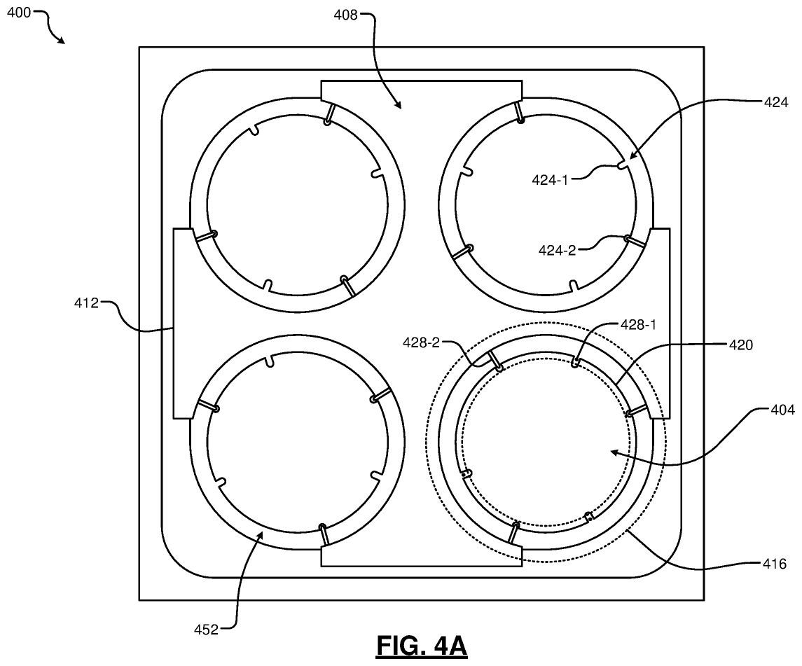

Referring to FIGS. 3A and 3B, example dowels 300 and 304 and corresponding slots 308 and 312 are shown. In some embodiments, the dowel 300 and the slot 308 may correspond to the dowel 228-1 and the slot 236-1 shown in FIG. 2C. In some embodiments, the dowel 304 and the slot 312 may correspond to the dowels 228-3 and the slot 236-3 in FIG. 2C. The dowel 300 is sized to be inserted within the slot 308 but not the slot 312. In other words, a diameter of the dowel 300 is selected such that the diameter of the dowel 300 is less than a width of the slot 308 but larger than a width of the slot 312. In some embodiments, the diameter of the dowel 300 is further reduced relative to the width of the slot 308 (but still larger than a width of the slot 312) to allow a greater range of movement within the slot to increase a maximum clocking range of the clockable pedestal 216.

For example, as shown in FIG. 3A, a diameter d1 of the dowel 300 is approximately (e.g., within +/−5% of) 0.200 inches (5.08 mm) and a width w1 of the slot 308 is 0.265 inches (6.731 mm). In other words, the diameter d1 of the dowel 300 is approximately (e.g., within +/−5% of) 0.065 inches (1.651 mm) less than the width w1 of the slot 308. Accordingly, when centered within the slot 308 in an x direction, the dowel 300 is permitted a range of movement of approximately +/−0.0325 inches (0.8255 mm) in the x direction (e.g., Δx). Conversely, the diameter d1 of the dowel 300 is at least 0.1 inches (2.54 mm) less than a length of the slot 308. Accordingly, when centered within the slot 308 in a y direction, the dowel 300 is permitted a range of movement of at least +/−0.050 inches (1.27 mm) in the y direction (e.g., Δy).

As shown in FIG. 3B, a diameter d2 of the dowel 304 is approximately (e.g., within +/−5% of) 0.125 inches (3.175 mm) and a width w2 of the slot 312 is 0.190 inches (4.826 mm). In other words, the diameter d2 of the dowel 304 is approximately (e.g., within +/−5% of) 0.065 inches (1.651 mm) less than (or 34-35% less than) the width w2 of the slot 312. As such, in this example, a difference between the diameter d2 of the dowel 304 and the width w2 of the slot 312 is the same as a difference between the diameter d1 of the dowel 300 and the width w1 of the slot 308. Accordingly, when centered within the slot 312 in the x direction, the dowel 304 is permitted a range of movement of approximately +/−0.0325 inches (0.8128 mm) in the x direction (e.g., Δx). Conversely, the diameter d2 of the dowel 304 is at least 0.1 inches (2.54 mm) less than a length of the slot 312. Accordingly, when centered within the slot 312 in the y direction, the dowel 304 is permitted a range of movement of at least +/−0.050 inches (1.27 mm) in the y direction (e.g., Δy). In some embodiments, the diameter d2 of the dowel 304 may be 20%-40% less than the width w2 of the slot 312 (e.g., 20%, 25%, 30%, 35%, or 40% less).

The diameters d1 and d2 of the dowels 300 and 304 and the widths w1 and w2 of the slots 308 and 312 are provided for example. However, the diameters d1 and d2 of the dowels 300 and 304 relative to the widths w1 and w2 of the slots 308 and 312, respectively, are selected to achieve a desired minimum range of movement of the dowels 300 and 304 (and, therefore, a range of movement of the clockable pedestal 216) in the x and y directions. For example, the diameter d1 of the dowel 300 may be at least 0.050 inches (1.27 mm) less than (or 24-25% less than) the width w1 of the slot 308 but at least 0.008 inches (0.2032 mm) greater than (or 5-6% greater than) the width w2 of the slot 312. As another example, the diameter d1 of the dowel 300 is approximately 75% (e.g., 70-80%) of the width of the slot 308. In some embodiments, the diameter d1 of the dowel 300 is approximately 60%-90% (e.g., 60%, 63%, 65%, 67%, 70%, 73%, 75%, 77%, 80%, 82%, 85%, 87%, or 89%) of the width of the slot 308.

Referring now to FIG. 3C and with continued referenced to FIGS. 20, 3A, and 3B, an example range of movement 320 of the clockable pedestal 216 in the x and y directions relative to the pedestal base 208 is illustrated. For example, the range of movement 320 is described relative to a center point 324 of the clockable pedestal 216 (e.g., a center of the clockable pedestal 216 when the clockable pedestal 216 is installed in the pedestal base 208). For example, the range of movement 320 is +/−0.0315 inches (0.8001 mm) in the x direction for a total range of movement 320 of 0.063 inches (1.6002 mm) in the x direction (e.g., Δx). Conversely, the range of movement 320 is +/−0.0375 inches (0.9525 mm) in the y direction for a total range of movement 320 of 0.075 inches (1.905 mm) in the y direction (e.g., Δy).

The specific range of movement 320 of the clockable pedestal is provided for example. However, the diameters d1 and d2 of the dowels 300 and 304 relative to the widths w1 and w2 of the slots 308 and 312, respectively, are selected as described above to achieve a desired minimum range of movement 320 of the clockable pedestal 216 in the x and y directions. For example, the diameters d1 and d2 of the dowels 300 and 304 relative to the widths w1 and w2 of the slots 308 and 312 are selected such that the range of movement 320 of the clockable pedestal 216 is at least +/−0.030 inches (e.g., 0.76 mm) in each of the x and y directions.

While the range of movement 320 as illustrated has a generally hexagonal shape (e.g., due to specific orientations of the slots 236 relative to one another and to the clockable pedestal 216 and associated constraints in the x and y directions), the range of movement 320 may have other shapes in other embodiments.

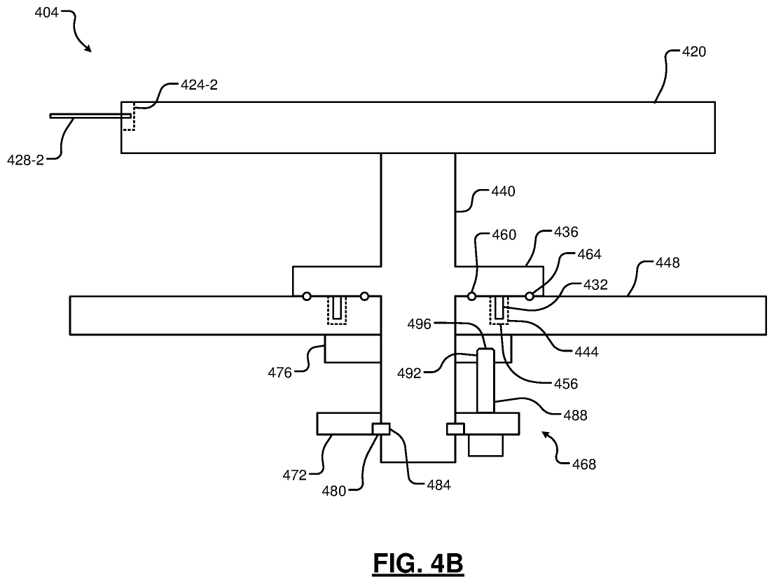

Referring now to FIGS. 4A and 4B, an example process module 400 comprising a plurality of clockable pedestal assemblies 404 according to some embodiments of the present disclosure is shown. FIG. 4A is a plan (e.g., top-down) view of the process module 400. FIG. 4B is a side cross-sectional view of an example of one of the clockable pedestal assemblies 404. A transfer plate 408 is shown arranged on the process module 400 in FIG. 4A. For example, the transfer plate 408 includes a plurality of transfer arms 412 arranged to hold and transfer carrier rings 416 to and from respective ones of the clockable pedestal assemblies 404. The carrier rings 416 are configured to hold a respective substrate and the transfer plate 408 aligns the carrier rings 416 with the clockable pedestal assemblies 404 for transfer of substrates to and from the clockable pedestal assemblies 404.

Each of the clockable pedestal assemblies 404 comprises a respective clockable pedestal 420 arranged as described above in FIGS. 2A-2C. Each of the clockable pedestals 420 comprises a plurality of alignment features 424, which may comprise a first set of alignment features 424-1 and a second set of alignment features 424-2. For example, the first set of alignment features 424-1 are arranged to facilitate alignment of the transfer plate 408 to the clockable pedestal assemblies 404. Conversely, the second set of alignment features 424-2 are arranged to facilitate alignment of the carrier rings 416 to the clockable pedestal assemblies 404. For example, the alignment features 424 comprise notches or recesses defined in a radially outer edge or perimeter of the clockable pedestal 420 (e.g., a baseplate or upper support surface of the clockable pedestal 420). As shown, the clockable pedestal 420 comprises three of each of the alignment features 424-1 and 424-2 (as shown) uniformly or non-uniformly spaced around the radially outer edge. In some embodiments, the clockable pedestal 420 may comprise fewer or more than three of each of the alignment features 424-1 and 424-2, a same or different number of the alignment features 424-1 and 424-2, etc.

The alignment features 424-1 are arranged to align with respective complementary alignment features (e.g., pins) 428-1 extending from a surface of the carrier rings 416. Conversely, the alignment features 424-2 are arranged to align with respective complementary alignment features (e.g., pins) 428-2 extending radially inward from the transfer arms 412.

As shown in FIG. 4B, the dowels 432 extend downward from a bottom plate 436 arranged around a stem 440 of the clockable pedestal 420. The dowels 432 are aligned with slots 444 defined in a surface of a pedestal base 448. As described above in FIGS. 2A-2C and 3A-3C, the dowels 432 are sized to maximize clocking range of movement of the clockable pedestal 420 while preventing insertion of the dowels 432 into the incorrect slot. The clocking range facilitates further alignment of the clockable pedestal 420 relative to the process module 400 and, correspondingly, relative to the transfer plate 408, the transfer arms 412, and the carrier rings 416. More specifically, the clocking range of the clockable pedestal 420 facilitates alignment of the alignment features 424 on the clockable pedestal 420 with the alignment features 428-1 and 428-2 of the transfer plate 408 and the carrier rings 416, respectively.

For example, the transfer plate 408 is aligned with the process module 400 such that openings (e.g., generally circular space) 452 defined between the transfer arms 412 are aligned with (e.g., centered or concentric relative to) the clockable pedestal 420. Accordingly, the carrier ring 416 supported on the transfer plate 408 are correspondingly aligned with the clockable pedestal 420. When the transfer plate 408, the carrier rings 416, and the clockable pedestal assemblies 404 are perfectly aligned with the process module 400 and to each other, none of the alignment features 428-1 and 428-2 contact any of the sidewalls of the alignment features 424 in the clockable pedestal 420 during transfer operations.

Conversely, when any of the transfer plate 408, the carrier rings 416, and the clockable pedestal assemblies 404 are not perfectly aligned (e.g., due to manufacturing tolerances, a limited clocking range of the clockable pedestal 420, etc.), one or more of the alignment features 428-1 and 428-2 may contact sidewalls of respective ones of the alignment features 424 during transfer operations. Contact between the alignment features 428-1 and 428-2 and the alignment features 424 (or between other surfaces of the transfer plate 408, the carrier rings 416, and the clockable pedestal assemblies 404) could cause vibration of various structures and may generate particles/contaminants. The clocking range of the clockable pedestals 420 according to the principles of the present disclosure as described above allow additional fine-tuning of the positions of the clockable pedestals 420 relative to the process module 400 to achieve a desired alignment between the alignment features 428-1 and 428-2 and the alignment features 424. In other words, once the clockable pedestals 420 are installed in the pedestal base 448, the relative sizes of the dowels 432 and the slots 444 allow additional movement of the clockable pedestals 420 to fine-tune the alignment.

As shown in FIG. 4B, when the clockable pedestal 420 is installed, the dowels 432 do not contact a bottom surface 456 of the slots 444. Accordingly, lateral movement of the dowels 432 within the slots 444 is not obstructed during fine-tuning of the alignment of the clockable pedestal 420 and particle generation caused by contact between the dowels 432 and the slots 444 is minimized. Further, as shown, the dowels 432 and slots 444 are located between (i.e., in a radial direction) a first seal or O-ring 460 and a second seal or O-ring 464. Accordingly, any particles generated by the contact between the dowels 432 and the slots 444 are sealed between the first O-ring 460 and the second O-ring 464.

When the clockable pedestal 420 is in a desired position, the clockable pedestal 420 may be secured to the process module 400 (e.g., to the pedestal base 448) to prevent subsequent movement and misalignment. For example, the clockable pedestal assembly 404 may include a clamp assembly 468 configured to clamp the clockable pedestal 420 to the pedestal base 448. In an example embodiment, the clamp assembly 468 includes a first (e.g., lower) clamping plate 472 and a second (e.g., upper) clamping plate 476 encircling a portion of the stem 440 below the pedestal base 448. In some embodiments, the second clamping plate 476 is optional and may be omitted.

The first clamping plate 472 is configured to bias the clockable pedestal 420 downward (i.e., in a direction away from the pedestal base 448). For example, a clamping ring 480 encircles the stem 440 and the first clamping plate 472 is supported on the clamping ring 480. In an embodiment, the clamping ring 480 is arranged and retained within a groove 484 in the stem 440. Accordingly, when the clamping ring 480 is biased downward, the clamping ring 480 and the stem 440 are pulled downward. In some embodiments, the clamping ring 480 may be an integrated feature of the first clamping plate 472. In some embodiments, clamping ring 480 may be an integrated feature of the stem 440.

As shown, the clamping assembly 468 includes one or more biasing mechanisms, such as a screw 488. In some embodiments, the screw 488 passes upward through the first clamping plate 472 into a pocket 492 defined within the second clamping plate 476. In embodiments where the second clamping plate 476 is omitted, the screw 488 contacts a lower surface of the pedestal base 448. In some embodiments, the screw 488 is configured such that as the screw 488 is tightened, the first clamping plate 472 is pulled/forced downward away from the pedestal base 448, which in turn causes the clamping ring 480, the stem 440, and the clockable pedestal 420 to be pulled downward and clamped to the pedestal base 448. In other words, the pedestal base 448 is clamped between the bottom plate 436 and the second clamping plate 476 to secure the clockable pedestal 420 against the pedestal base 448.

A clamping (e.g., upper) end 496 of the screw 488 is flat (or generally flat) to maximize clamping force against the second clamping plate 476 or the pedestal base 448. Further, the flat clamping end 496 increases contact surface area between the screw 488 and the second clamping plate 476 to minimize movement of the clockable pedestal 420. In embodiments, the screw 488 does not include lubricant. Threads of the screw 488 may include a coating or plating (e.g., silver, Teflon, etc.) to reduce galling.

The foregoing description is merely illustrative in nature and is in no way intended to limit the disclosure, its application, or uses. The broad teachings of the disclosure can be implemented in a variety of forms. Therefore, while this disclosure describes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, such as “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, such as a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, such as the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may comprise chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may comprise a local network or the Internet. The remote computer may comprise a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may comprise a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A clockable pedestal configured to support a substrate in a processing station of a substrate processing system, the clockable pedestal comprising:
a baseplate;
a stem that extends in a first direction from the baseplate; and
a plurality of dowels arranged around the stem that extend in the first direction from the clockable pedestal, wherein the plurality of dowels comprises at least a first dowel, a second dowel, and a third dowel, wherein
each of the plurality of dowels is configured to be inserted within a respective one of a plurality of slots in a first surface of the processing station, wherein the plurality of slots comprises a first slot, a second slot, and a third slot, and wherein a width of the first slot is greater than widths of each of the second slot and the third slot, and
a diameter of the first dowel is greater than diameters of each of the second dowel and the third dowel, wherein the diameter of the first dowel is less than the width of the first slot and greater than the widths of the second slot and the third slot.

2. The clockable pedestal of claim 1, wherein the diameter of the first dowel is 70-80% of the width of the first slot.

3. The clockable pedestal of claim 1, wherein the plurality of dowels are evenly circumferentially spaced around the stem,

4. The clockable pedestal of claim 1, wherein the clockable pedestal comprises a bottom plate arranged around the stem below the baseplate, and wherein the dowels extend downward from the bottom plate.

5. The clockable pedestal of claim 1, wherein the diameters of the second dowel and the third dowel are the same and the widths of the second slot and the third slot are the same.

6. The clockable pedestal of claim 1, wherein the diameter of the first dowel is at least 24% less than the width of the first slot and at least 5% greater than the widths of the second slot and the third slot.

7. The clockable pedestal of claim 6, wherein the diameters of the second dowel and the third dowel are approximately 34-35% less than the widths of the second slot and the third slot, respectively.

8. The clockable pedestal of claim 1, wherein a range of movement of the first dowel within the first slot is at least +/−0.76 mm in an x direction.

9. The clockable pedestal of claim 1, wherein a range of movement of the clockable pedestal when installed within the processing station is at least +/−0.76 mm in each of an x direction and a y direction perpendicular to the x direction.

10. A process module comprising a plurality of processing stations and further comprising at least four of the clockable pedestals of claim 1 arranged in respective ones of the plurality of processing stations.

11. A clockable pedestal assembly configured to support a substrate in a process module of a substrate processing system, the clockable pedestal assembly comprising:
a clockable pedestal comprising
a baseplate,
a plurality of alignment features defined in a radially outer edge of the baseplate,
a stem that extends downward from the baseplate, and
a plurality of dowels comprising a first dowel, a second dowel, and a third dowel arranged around the stem, wherein
the first dowel, the second dowel, and the third dowel are aligned with and configured to be received by a plurality of slots comprising a first slot, a second slot, and a third slot, respectively, in a first surface of the process module,
a diameter of the first dowel is greater than diameters of each of the second dowel and the third dowel, wherein the diameter of the first dowel is less than a width of the first slot and greater than widths of the second slot and the third slot, and
the plurality of dowels and the plurality of slots are sized to allow clocking of (i) the clockable pedestal and (ii) the plurality of alignment features.

12. The clockable pedestal assembly of claim 11, wherein the plurality of alignment features comprises a plurality of notches defined in the radially outer edge of the baseplate.

13. The clockable pedestal assembly of claim 11, wherein the clockable pedestal comprises a bottom plate arranged around the stem below the baseplate, and wherein the plurality of dowels extend from the bottom plate.

14. The clockable pedestal assembly of claim 13, further comprising a first O-ring and a second O-ring disposed between the bottom plate and the first surface, wherein the plurality of dowels is located between the first O-ring and the second O-ring.

15. The clockable pedestal assembly of claim 11, wherein the diameters of the second dowel and the third dowel are the same and the widths of the second slot and the third slot are the same.

16. The clockable pedestal assembly of claim 11, wherein the diameter of the first dowel is approximately 24-25% less than the width of the first slot.

17. The clockable pedestal assembly of claim 16, wherein the diameters of the second dowel and the third dowel are approximately 34-35% less than the widths of the second slot and the third slot, respectively.

18. The clockable pedestal assembly of claim 11, wherein a range of movement of the clockable pedestal when installed within the process module is at least +/−0.76 mm in each of an x direction and a y direction perpendicular to the x direction.

19. The clockable pedestal assembly of claim 11, further comprising a clamp assembly configured to clamp the clockable pedestal to a pedestal base of the process module.

20. A process module comprising a plurality of processing stations and further comprising at least four of the clockable pedestal assemblies of claim 11 arranged in respective ones of the plurality of processing stations.
